(19) United States
(12) Patent Application Publication
(10) Pub. No.: US 2007/0181532 A1
(43) Pub. Date: Aug. 9, 2007

(54) CMP CLEAN PROCESS FOR HIGH PERFORMANCE COPPER/LOW-K DEVICES

(75) Inventors: Mona M. EISSA, Allen, TX (US); Nilesh S. Doke, Allen, TX (US); Eden M. Zielinski, Richardson, TX (US); Gregory B. Shinn, Dallas, TX (US)

Correspondence Address: TEXAS INSTRUMENTS INCORPORATED, P O BOX 655474, M/S 3999, DALLAS, TX, 75265, US

(73) Assignee: Texas Instruments, Incorporated

(21) Appl. No.: 11/734,061

(22) Filed: Apr. 11, 2007

Related U.S. Application Data
(63) Continuation of application No. 10/950,979, filed on Sep. 27, 2004.
(60) Provisional application No. 60/568,331, filed on May 4, 2004.

(51) Int. Cl. B08B 3/00; B44C 1/22; H01L 21/302; H01L 21/461

(52) U.S. Cl. 216/83; 438/745; 438/734; 134/26

(57) ABSTRACT

A post chemical-mechanical polishing cleaning method, comprising contacting a die with a first chemistry that removes at least some organic compounds and ions from a surface of the die. After contacting the die with the first chemistry, the method further comprises contacting the die with a second chemistry that removes at least some copper abutting the die surface. The method further comprises rinsing and drying the die.

### CROSS-REFERENCE TO RELATED APPLICATIONS

This application is a non-provision application claiming priority to provisional application Ser. No. 60/568,331 filed on May 4, 2004, which is hereby incorporated by reference.

### BACKGROUND

Integrated circuits are fabricated on the surface of a semiconductor wafer in layers, and later singulated into individual semiconductor devices, or “dies.” Many fabrication processes are repeated numerous times, constructing layer after layer until fabrication is complete. Metal layers, which typically increase in number as device complexity increases, include patterns of conductive material that are vertically insulated from one another by alternating layers of insulating material. Conductive traces are also separated within each layer by an insulating, or dielectric, material. Vertical, conductive tunnels called “vias” typically pass through insulating layers to form conductive pathways between adjacent conductive patterns. Defects in semiconductor devices may result from, among other things, diffusion of mobile species and deficiencies in the layers of materials forming device structures. As design rules continue to mandate smaller designs, yields and reliability are more profoundly impacted by lower and lower levels of contaminants.

Cleaning a wafer/die after chemical-mechanical polishing (“CMP”) presents the problem of effectively removing contaminants/residues from a hydrophobic (i.e., water-aversive) surface. The CMP process may expose a low K dielectric material (a dielectric material having a K value of about 3 or less) that surrounds a metal line or contact. One characteristic of such a low K dielectric material is the hydrophobic quality of its surface. Further, as designs shrink, the problem may be enhanced because lower K dielectric materials are needed around metals, and, typically, the lower the K-value of the material, the more hydrophobic its surface. The CMP process typically introduces contaminants such as organic, ionic, metallic, and organo-metallic residues and species. Such contaminants may be difficult to remove reliably because of the hydrophobic nature of the dielectric surface. Cleaning processes used to eliminate these contaminants generally have at least three undesirable side effects: copper corrosion, high adhesive strength of post-polish residue defects to hydrophobic dielectric surfaces, and the formation of stains and water marks during the drying of the hydrophobic dielectric surface, leaving residual chemical contaminants on the wafer surface. One past solution to this problem involves use of a hydrophilic “cap” on the low K dielectric, which promotes a more thorough removal of contaminants following chemical-mechanical polishing. While the addition of a hydrophilic cap may resolve some of the problems associated with these cleaning processes, the cap also increases the effective low K dielectric of the associated device, thus causing decreased performance levels.

### SUMMARY

The problems noted above are solved in large part by a post chemical-mechanical polishing cleaning method comprising contacting a die with a first chemistry that removes at least some organic compounds and ions from a surface of the die. After contacting the die with the first chemistry, the method further comprises contacting the die with a second chemistry that removes at least some contaminated metal and metal-containing compounds from the die surface by etching away at least some copper abutting the die surface. The method further comprises rinsing and drying the die.

Another embodiment may be a system for cleaning a die following chemical-mechanical polishing, comprising a first chemistry vessel adapted to remove organic compounds and ions from a die surface, a second chemistry vessel adapted to remove contaminated metal and metal-containing compounds from the die surface by removing at least some copper abutting the die surface, and a dryer adapted to rinse and dry the die, wherein the dryer is one of a spin-rinse dryer or an isopropanol dryer.

Yet another embodiment may be a method comprising fabricating a die using a fabrication device with a process technology rated at a maximum of approximately 120 nanometers, contacting the die with a first chemistry that removes at least some organic compounds and ions from a surface of the die, and, after contacting the die with the first chemistry, contacting the die with a second chemistry that removes contaminants by etching away at least some copper abutting the die surface.

### BRIEF DESCRIPTION OF THE DRAWINGS

For a detailed description of exemplary embodiments of the invention, reference will now be made to the accompanying drawings in which:

FIG. 1 shows a fabrication device and a series of vessels through which an embodiment of a cleaning method following chemical-mechanical polishing may be performed;

FIG. 2 shows a fabrication device and another series of vessels through which another embodiment of a cleaning method following chemical-mechanical polishing may be performed; and

FIG. 3 shows a cross-sectional side view of a die having a copper and dielectric surface cleaned using the technique(s) described in FIGS. 1 and/or 2.

### NOTATION AND NOMENCLATURE

Certain terms are used throughout the following description and claims to refer to particular system components. As one skilled in the art will appreciate, companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . . ” Also, the term “couple” or “couples” is intended to mean either an indirect or direct electrical connection. Thus, if a first device couples to a second device, that connection may be through a direct electrical connection, or through an indirect electrical connection via other devices and connections.

The term “integrated circuit” or “IC” refers to a set of electronic components and their interconnections (internal electrical circuit elements, collectively) that are patterned on the surface of a microchip. The term “semiconductor device” refers generically to an integrated circuit (IC). The term “die” (“dies” for plural) refers generically to an integrated circuit or semiconductor device, which may be a portion of a wafer, in various stages of completion, including the underlying semiconductor substrate, insulating materials, and all circuitry patterned thereon.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

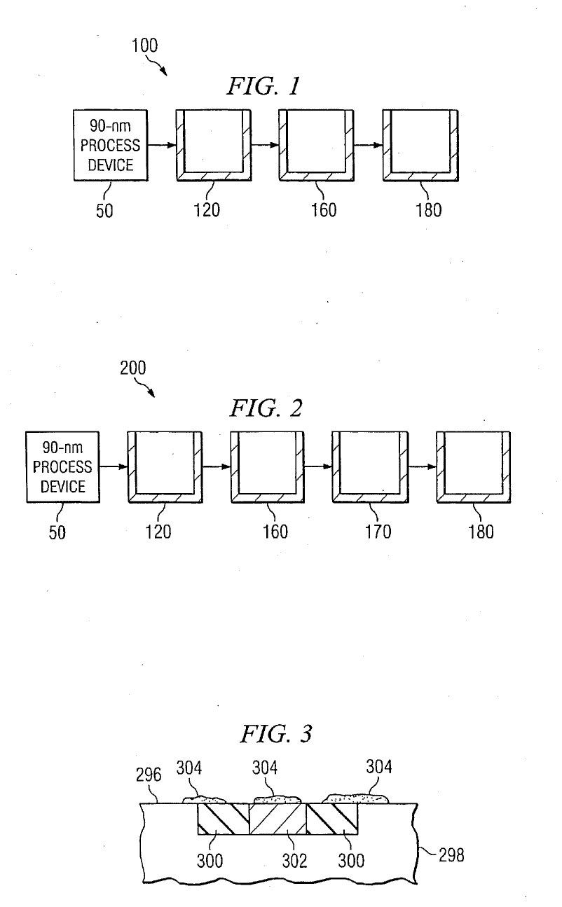

FIG. 1 depicts a fabrication device 50 and a series of vessels 100 through which an embodiment of a cleaning method following chemical-mechanical polishing (or “post-CMP clean”) may be performed. Chemical-mechanical polishing (CMP) and a post-CMP clean are typically associated with preparation of metal device structures, such as copper lines. In an embodiment, a die, or wafer is first fabricated using, for example, a 90-nm fabrication device 50. The scope of disclosure is not limited to 90-nm process technology; other technologies, such as 65-nm process technology, 120-nm process technology, 45-nm process technology, sub-45-nm process technology or any other process technology also may be used. After fabricating the die and, among other things, performing a CMP process on the die, the die is introduced to a first vessel 120 containing an acid having, in at least some embodiments, a pH level between approximately 2.8 and 5.5 (“low pH acid”). Then, the die is contacted with an acid having, in at least some embodiments, a pH level between approximately 8.5 and 12.5 (“high pH acid”) in a second vessel 160, followed by a spin-rinse dry cycle in a dryer 180. In various embodiments, contacting with the high pH acid 160 etches away at least approximately 10 angstroms of metal height, e.g., copper.

The high pH acid may be an organic acid and, as described above, in various embodiments may comprise a pH from about 8.5 to about 12.5. An example of an appropriate, commercially available organic acid is ESCT794® sold by ATMIO®. The concentration of the high pH acid may be of concern. In some versions, the high pH acid solution comprises or is formed from about 0.8 to about 3 weight percent acid and the remainder deionized water; alternatively, the high pH acid solution comprises from about 0.9 to about 2 weight percent acid and the remainder deionized water.

The post-CMP cleaning method described herein may eliminate the need for a hydrophilic cap in order to promote effective removal of residues and contaminants after CMP. The method also may relax the time window within which a hermetically sealed cap layer may be deposited so as to inhibit further copper corrosion. It is believed the proper employment of a high pH acid overcomes the hydrophobic characteristics of the low K dielectric material by the acid's ability to etch metal such as copper and maintain negative zeta potential for at least some species that will cause repulsion between by-products and the die surface. In some embodiments, the high pH acid removes from about 10 to about 150 angstroms of copper height. By etching copper, it is believed the high pH acid effectively removes a top layer of copper that is typically dirty after CMP; and effectively removes copper-containing or organometallic, metal/copper bi-product-containing, residues, contaminants (e.g., Copper I and/or Copper II species), or stains that may also be present on the surface of the dielectric material. In at least some embodiments, hydrophilic material or any other suitable material may be used in lieu of hydrophobic material.

The low pH acid (e.g., a chemistry comprising an organic acid) is used to remove organic compounds and ions, e.g., calcium and potassium ions, from the surface of the die as a part of the post-CMP clean. As described above, in some embodiments, the low pH acid comprises a pH from about 2.8 to about 5.5. An example of an appropriate, commercially available low pH acid is ElectraClean® by Ashland Chemical Corporation®. The concentration of the low pH acid may be of concern. In some versions, the low pH acid solution comprises or is formed from about 1 to about 5 weight percent acid and the remainder deionized water; alternatively, the low pH acid solution comprises from about 2 to about 4 weight percent acid and the remainder deionized water.

FIG. 2 depicts a system 200 for performing an embodiment of a post-CMP clean. The system comprises a 90-nm fabrication device 50 (may be substituted with any suitable device, such as a 65-nm device, 120-nm device, 50-nm device, and so forth), a low pH acid vessel 120, a first high pH acid vessel 160, a second high pH acid vessel 170, and a dryer (e.g., spin rinse, isopropanol (IPA), or any other type of dryer) 180 for performing a rinse-dry sequence employing deionized water. The device 50 may use any of the aforementioned process technologies to fabricate a die. After CMP and any other applicable processes, the die may be cleaned using the vessels 120-180. The first high pH acid vessel 160 and second high pH acid vessel 170 contain a high pH acid for, among other things, removing contaminated metal or metal-containing, especially copper-containing, compounds from the surface of the die/wafer.

Process parameters in the first high pH acid vessel 160 and second high pH acid vessel 170 may vary. In various embodiments, one or both of the vessels 160, 170 comprise a contact mechanical mechanism such as a brush cleaning mechanism, or a non-contact mechanical mechanism, such as megasonic and/or ultrasonic power mechanisms. In certain embodiments, the contact-cleaning mechanism is a brushing tool inside the vessel that brushes the surface of the die to facilitate contacting and cleaning. An example of a commercial vessel that may be equipped with such a contact-cleaning and/or non-contact mechanism is the Mirra/Mesa® tool produced by Applied Materials®. Temperature may also be a parameter of concern in the first high pH acid vessel 160 and second high pH vessel 170. Suitable temperatures in the high pH acid vessels 160, 170 may be in the range from about 20 to about 40 degrees Celsius.

Since the high pH acid (e.g., a chemistry comprising an organic acid) in the high pH acid vessels 160, 170 is capable of etching the metal exposed after CMP, process time, among other parameters, such as temperature, acid pH, and acid concentration, may be monitored for optimized etching and cleaning. In embodiments, a die subjected to the post-CMP clean described herein may be contacted with a high pH acid in a high pH acid vessel for from about 1 second to about 2 minutes. Where two high pH acid vessels are employed, such as in the embodiment of FIG. 2, the combined, total cleaning time in the first high pH acid vessel 160 and second high pH acid vessel 170 may be from about 1 second to about 2 minutes. In some embodiments where two high pH acid vessels are employed, the allotted cleaning time is divided evenly between vessels. In other embodiments, the cleaning time may be greater in the first high pH acid vessel 160, or in the second high pH acid vessel.

Process parameters in the low pH acid vessel 120 may vary. In some embodiments, a die may be cleaned in the low pH acid vessel 120 for preferably between 1 second and 5 minutes, although the die may be cleaned for any suitable length of time. The vessel 120 temperature preferably is between approximately 23 and 60 degrees Celsius, although the scope of disclosure is not limited to this temperature range. The low pH acid vessel 120 may use a contact mechanical mechanism such as a brush-cleaning mechanism, or a non-contact mechanical mechanism such as a megasonic and/or ultrasonic mechanism, or any other type of cleaning mechanism.

FIG. 3 illustrates a die 298 comprising a copper trace 302 fixed between two dielectric layers 300. A contaminated material layer 304 (e.g., contaminated copper, organic compounds and ions) abuts a surface 296 of the die 298. At least a portion of the contaminated material layer 304 (e.g., organic compounds and ions) may be removed by the acid in the low pH acid vessel 120 of FIGS. 1 and 2. Remaining portions of the contaminated material layer 304 (e.g., contaminated copper) may be removed by the acid in the high pH acid vessel 160 and/or the vessel 170. The high pH acid contained therein may etch a substantially thin slice of the copper trace 302 on the surface 296 such that most or all contaminants in the contamination material layer 304 are removed. Likewise, the high pH acid may etch away copper contaminants found in portions of the contaminated material layer 304 abutting the dielectric layers 300. In this way, the surface 296 of the die 298 is cleaned of contaminants and copper trace 302 is freed of Copper I, II oxides.

The effectiveness of the low pH acid and high pH acid cleaning combination permits employment of a spin-rinse dryer 180 as the terminal step in the post-CMP clean. That is, despite the hydrophobic nature of the low K dielectric material to be cleaned and rinsed, which previously may have required employment of an isopropyl alcohol dryer. The sequence in the dryer 180 of spinning while rinsing with deionized water and then spinning to dry is typical of those methods employed by one skilled in the art.

The above discussion is meant to be illustrative of the principles and various embodiments of the present invention. Numerous variations and modifications will become apparent to those skilled in the art once the above disclosure is fully appreciated. For example, while the subject matter above is primarily presented in the context of hydrophobic material, any other material (e.g., hydrophilic material) also may be used. It is intended that the following claims be interpreted to embrace all such variations and modifications.

1. A post chemical-mechanical polishing cleaning method, comprising:
contacting a die with a first chemistry that removes at least some organic compounds and ions from a surface of the die;
after contacting the die with the first chemistry, contacting the die with a second chemistry that removes at least some contaminated metal and metal-containing compounds from the die surface by etching away at least some copper abutting the die surface; and
after contacting the die with the second chemistry, rinsing and drying the die.

2. The method of claim 1 wherein etching away at least some copper comprises reducing a copper layer height by at least 10 angstroms and dissolving at least some copper oxides.

3. The method of claim 1 wherein contacting the die with the second chemistry comprises using a chemistry having a pH level between approximately 8.5 and approximately 12.5.

4. The method of claim 1 wherein contacting the die with the first chemistry comprises using a chemistry having a pH level between approximately 2.8 and approximately 5.5.

5. The method of claim 1 wherein contacting the die with the second chemistry comprises using a chemistry having or formed from:
between approximately 0.8 and approximately 3 weight percent organic acid; and
between about 97 and about 99.2 weight percent deionized water.

6. The method of claim 1 wherein contacting the die with the first chemistry comprises using a chemistry having or formed from:
between about 1 and about 5 weight percent organic acid; and
between approximately 95 and approximately 99 percent deionized water.

7. The method of claim 1 wherein contacting the die with the first chemistry and contacting the die with the second chemistry comprise using at least one of a vessel having a megasonic cleaning mechanism or a vessel having a contact cleaning mechanism.

8. A system for cleaning a die following chemical-mechanical polishing, comprising:
a first chemistry vessel adapted to remove organic compounds and ions from a die surface;
a second chemistry vessel adapted to remove contaminated metal and metal-containing compounds from the die surface by removing at least some copper abutting the die surface; and
a dryer adapted to rinse and dry the die;
wherein the dryer is one of a spin-rinse dryer or an isopropanol dryer.

9. The system of claim 8 wherein the second chemistry vessel is adapted to remove contaminated metal and metal-containing compounds from the die surface within approximately 2 minutes.

10. The system of claim 8 wherein the first chemistry vessel is adapted to remove organic compounds and ions from the die surface within about 5 minutes.

11. The system of claim 8 wherein the second chemistry vessel comprises at least one of a contact-cleaning mechanism or a non-contact cleaning mechanism.

12. The system of claim 8 wherein the first chemistry vessel comprises at least one of a megasonic cleaning mechanism or a contact-cleaning mechanism.

13. The system of claim 8 wherein the second chemistry vessel operates at a temperature between approximately 20 degrees and approximately 40 degrees Celsius.

14. The system of claim 8 wherein the first chemistry vessel operates at a temperature between approximately 23 degrees and approximately 60 degrees Celsius.

15. The system of claim 8 wherein the first chemistry vessel comprises a chemistry having a pH level between approximately 2.8 and 5.5.

16. The system of claim 8 wherein the second chemistry vessel comprises a chemistry having a pH level between approximately 8.5 and 12.5.

17. The system of claim 8 wherein the first chemistry vessel comprises a chemistry having a composition selected from a group consisting of:
between approximately 1 and 5 weight percent organic acid and between approximately 95 to 99 weight percent deionized water; and
between approximately 2 and 4 weight percent organic acid and between approximately 96 to 98 weight percent deionized water.

18. The system of claim 8 wherein the second chemistry vessel comprises a chemistry having a composition selected from a group consisting of:
between approximately 0.8 and 3 weight percent organic acid and between approximately 97 to 99.2 weight percent deionized water; and
between approximately 0.9 and 2 weight percent organic acid and between approximately 98 to 99.1 weight percent deionized water.

19. The system of claim 8 wherein at least some of the copper is removed by reducing a copper layer height by at least 10 angstroms and dissolving at least some copper oxides.

20. The system of claim 8 wherein the die surface comprises at least one of a hydrophobic dielectric material or a hydrophilic dielectric material.

21. The system of claim 8 wherein the at least one of the chemistries in the first chemistry vessel and the second chemistry vessel comprises organic acid.

22. A method, comprising:
fabricating a die using a fabrication device with a process technology rated at a maximum of approximately 120 nanometers;
contacting the die with a first chemistry that removes at some organic compounds and ions from a surface of the die; and
after contacting the die with the first chemistry, contacting the die with a second chemistry that removes contaminants by etching away at least some copper abutting the die surface.

23. The method of claim 22 wherein using the fabrication device comprises using a sub-65 nm device.

24. The method of claim 22 wherein contacting the die with the first chemistry comprises using a chemistry having a pH of between approximately 2.8 and approximately 5.5.

25. The method of claim 22 wherein contacting the die with the second chemistry comprises using a chemistry having a pH of between approximately 8.5 and approximately 12.5.
